(19) United States
(12) Patent Application Publication
(10) Pub. No.: US 2024/0203960 A1
(43) Pub. Date: Jun. 20, 2024

(54) SEMICONDUCTOR PACKAGE

(71) Applicant: Samsung Electronics Co., Ltd., Suwon-si (KR)

(72) Inventor: Seokhyun Lee, Suwon-si (KR)

(21) Appl. No.: 18/485,378

(22) Filed: Oct. 12, 2023

(30) Foreign Application Priority Data
Dec. 19, 2022 (KR) 10-2022-0178649

(51) Int. Cl. H01L 25/10; H01L 23/00; H10B 80/00

(52) U.S. Cl. CPC H01L 25/105; H01L 24/16; H01L 24/32; H01L 24/33; H01L 24/73; H10B 80/00; H01L 2224/16145; H01L 2224/16227; H01L 2224/32145; H01L 2224/32225; H01L 2224/33519; H01L 2224/73253; H01L 2225/1005; H01L 2924/1431; H01L 2924/1436; H01L 2924/1438

(57) ABSTRACT

A semiconductor package includes a first semiconductor chip, a connection die adjacent a side surface of the first semiconductor chip, and a second semiconductor chip on the first semiconductor chip and the connection die. The first semiconductor chip includes a plurality of first through electrodes. The connection die includes a plurality of second through electrodes. The first through electrodes and the second through electrodes are below and vertically overlap the second semiconductor chip.

### CROSS-REFERENCE TO RELATED APPLICATION

This U.S. nonprovisional application claims priority under 35 U.S.C § 119 to Korean Patent Application No. 10-2022-0178649, filed on Dec. 19, 2022 in the Korean Intellectual Property Office, the disclosure of which is hereby incorporated by reference in its entirety.

### BACKGROUND

The present inventive concepts relate to a semiconductor package including a plurality of semiconductor chips.

In accordance with rapid development of the electronic industry and user's needs, an electronic device has a compact size, multi-functionality, and high capacity, and thus a semiconductor package includes a plurality of semiconductor chips.

An increase in integration of the plurality of semiconductor chips included in the semiconductor package causes printed circuit boards to often fail to accommodate such high integration. To solve the problem, semiconductor packages are being developed to use an interposer to connect the plurality of semiconductor chips to each other.

### SUMMARY

Some embodiments of the present inventive concepts provide a semiconductor package in which an electrical path between a plurality of semiconductor chips is reduced to increase reliability of the semiconductor package.

According to some embodiments of the present inventive concepts, a semiconductor package may include: a first semiconductor chip; a connection die adjacent a side surface of the first semiconductor chip; and a second semiconductor chip on the first semiconductor chip and the connection die. The first semiconductor chip may include a plurality of first through electrodes. The connection die may include a plurality of second through electrodes. The first through electrodes and the second through electrodes may be below and vertically overlap the second semiconductor chip.

According to some embodiments of the present inventive concepts, a semiconductor package may include: a first semiconductor chip; a connection die horizontally spaced apart from a side surface of the first semiconductor chip; and a second semiconductor chip on the first semiconductor chip and the connection die. Each of the first semiconductor chip and the connection die may include a plurality of through electrodes. The second semiconductor chip may vertically overlap an outer section of the first semiconductor chip and at least a portion of the connection die, and a central section of the first semiconductor chip may be horizontally offset from the second semiconductor chip.

According to some embodiments of the present inventive concepts, a semiconductor package may include: a package substrate; a logic chip on the package substrate; a first connection die and a second connection die that are spaced apart in a first direction from each other with the logic chip therebetween; a first sub-semiconductor package on the logic chip and the first connection die; and a second sub-semiconductor package on the logic chip and the second connection die. A spacing distance in the first direction between the first sub-semiconductor package and the second sub-semiconductor package may be less than a width in the first direction of the logic chip. Each of the first sub-semiconductor package and the second sub-semiconductor package may include: a base chip; a plurality of memory chips on the base chip; and a mold structure on the base chip and the memory chips. Each of the logic chip, the first connection die, the second connection die, the base chip, and the memory chips may include a plurality of through electrodes.

### BRIEF DESCRIPTION OF THE DRAWINGS

FIG. 1 illustrates a simplified perspective view showing a semiconductor package according to some embodiments of the present inventive concepts.

FIG. 2 illustrates a simplified plan view showing a semiconductor package according to some embodiments of the present inventive concepts.

FIG. 3 illustrates a cross-sectional view taken along line I-I′ of FIG. 2.

FIG. 4 illustrates a simplified plan view showing a bottom surface of a first semiconductor chip depicted in FIG. 3.

FIG. 5 illustrates a simplified plan view showing a bottom surface of a second semiconductor chip depicted in FIG. 3.

FIG. 6 illustrates an enlarged view showing portion AA of FIG. 3.

FIG. 7 illustrates a simplified cross-sectional view showing a semiconductor package according to some embodiments of the present inventive concepts.

FIG. 8 illustrates a simplified cross-sectional view showing a semiconductor package according to some embodiments of the present inventive concepts.

FIG. 9 illustrates a simplified cross-sectional view showing a semiconductor package according to some embodiments of the present inventive concepts.

### DETAILED DESCRIPTION

The following will now describe some embodiments of the present inventive concepts in conjunction with the accompanying drawings.

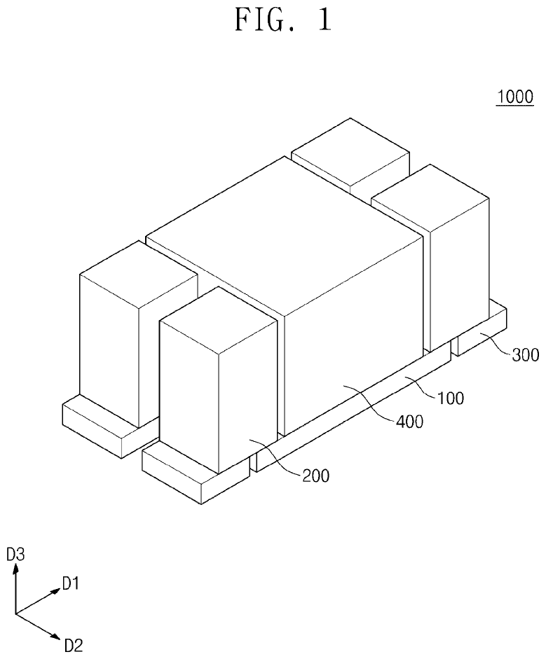

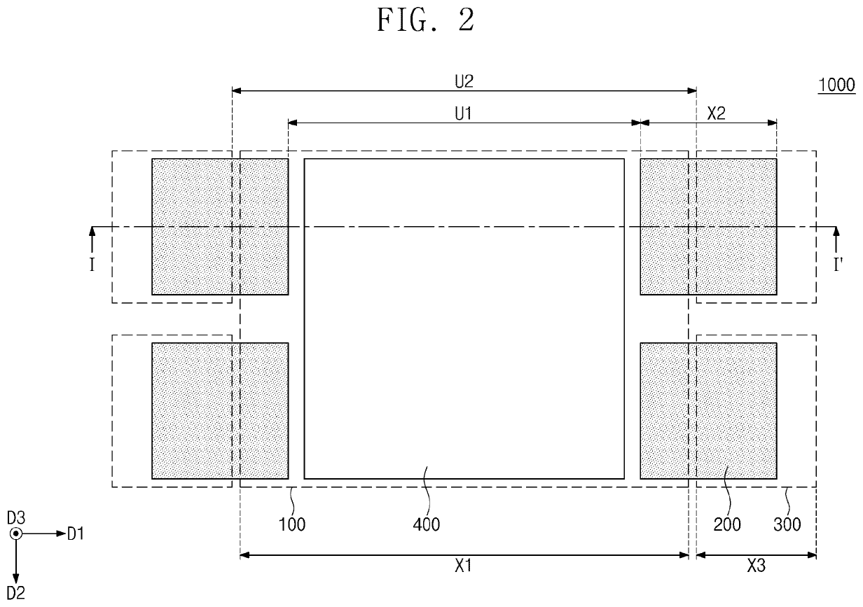

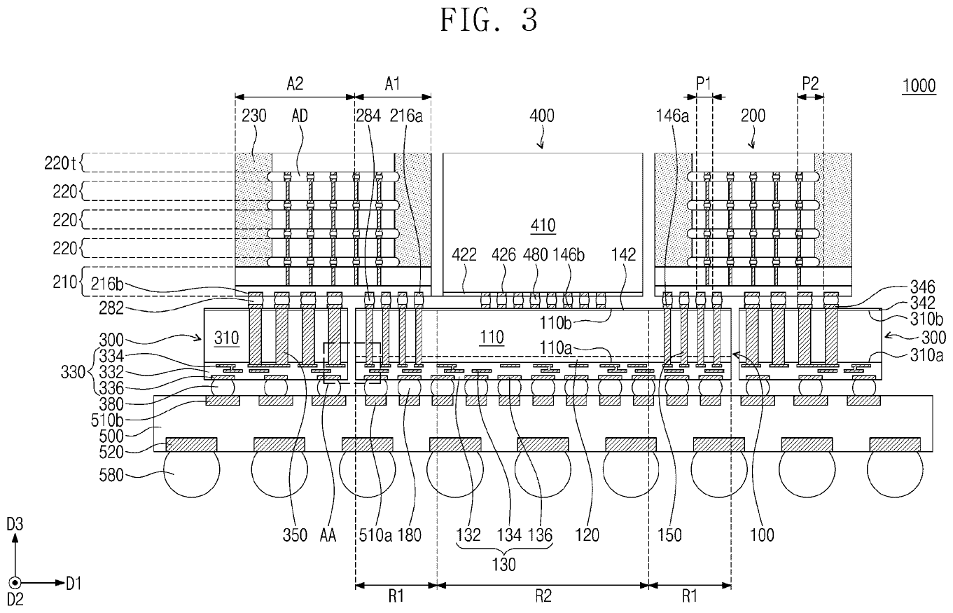

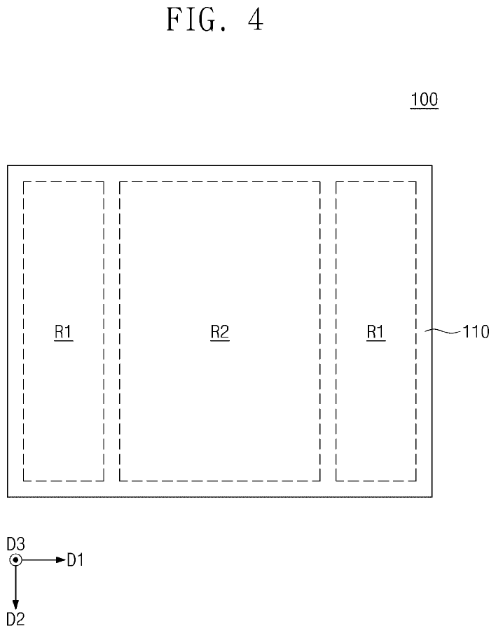

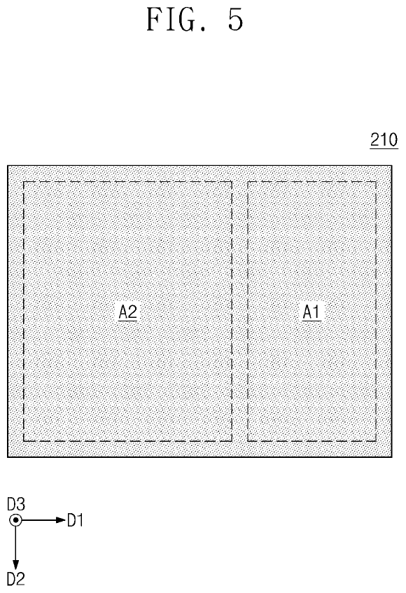

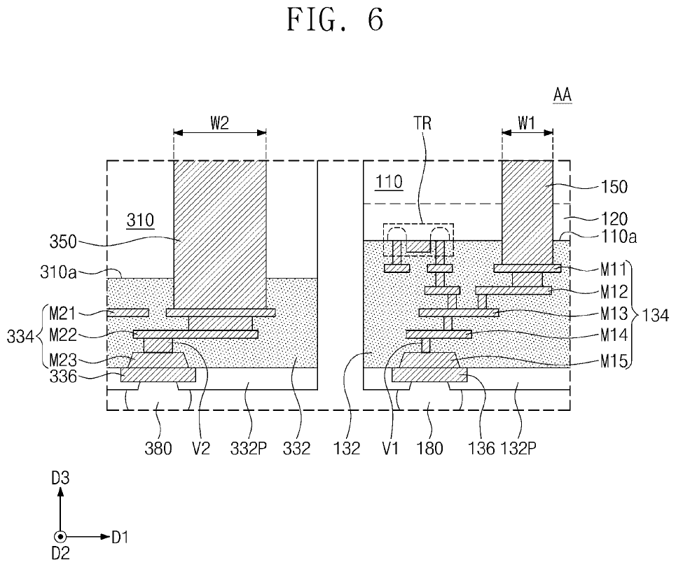

FIG. 1 illustrates a simplified perspective view showing a semiconductor package according to some embodiments of the present inventive concepts. FIG. 2 illustrates a simplified plan view showing a semiconductor package according to some embodiments of the present inventive concepts. FIG. 3 illustrates a cross-sectional view taken along line I-I′ of FIG. 2. FIG. 4 illustrates a simplified plan view showing a bottom surface of a first semiconductor chip depicted in FIG. 3. FIG. 5 illustrates a simplified plan view showing a bottom surface of a second semiconductor chip depicted in FIG. 3. FIG. 6 illustrates an enlarged view showing portion AA of FIG. 3. In FIGS. 1, 2, 4, and 5, some components are omitted to clearly disclose the present inventive concepts.

Referring to FIGS. 1, 2, and 3, a semiconductor package 1000 according to an embodiment of the present inventive concepts may include a first semiconductor chip 100, at least one connection die 300, and at least one sub-semiconductor package 200. In this description, the sub-semiconductor package 200 may be called a chip stack or a high bandwidth memory (HBM).

In this description, a semiconductor chip may mean a device in which an integrated circuit (IC) is formed on a semiconductor substrate. A semiconductor chip may indicate a product that is fabricated by a front-end-of-line (FEOL) process, a back-end-of-line (BEOL) process, and a wafer sawing process. A die may mean a semiconductor substrate on which no integrated circuit is formed. A die may indicate a product that is fabricated by a back-end-of-line (BEOL) process and a wafer sawing process, without a front-end-of-line (FEOL) process.

In this description, the phrase “a certain component is connected or coupled to a different component” may be interpreted as that “the certain component is directly connected to or directly coupled to the different component” or “an intervening element is present between the certain component and the different component.” The phrase “a certain component is in contact with a different component” may mean that “no intervening element is interposed between the certain component and the different component.”

The first semiconductor chip 100 and the connection die 300 may be spaced apart from each other in a horizontal direction. The connection die 300 may be disposed on or adjacent a lateral or side surface of the first semiconductor chip 100.

As shown in FIGS. 1 and 2, the first semiconductor chip 100 may be surrounded by four connection dies 300. In this case, two connection dies 300 may be correspondingly disposed on two facing or opposite lateral or side surfaces of the first semiconductor chip 100.

The sub-semiconductor package 200 may be disposed on the first semiconductor chip 100 and the connection die 300. For example, the sub-semiconductor package 200 may be disposed on a portion of the first semiconductor chip 100 and at least a portion of the connection die 300. When viewed in plan as shown in FIG. 2, the sub-semiconductor package 200 may vertically overlap a portion of the first semiconductor chip 100 and at least a portion of the connection die 300. The sub-semiconductor package 200 may vertically overlap an outer section or outer side portion or edge of the first semiconductor chip 100 and at least a portion of the connection die 300. A central section of the first semiconductor chip 100 may be exposed from the sub-semiconductor package 200. In other words, the sub-semiconductor package 200 may not vertically overlap a central portion of the first semiconductor chip 100.

The semiconductor package 1000 may further include a dummy die 400 disposed on the first semiconductor chip 100.

A detailed description of each component will be provided below. The first semiconductor chip 100 may be a logic chip. The first semiconductor chip 100 may be, for example, one of a central processing unit (CPU), a graphic processing unit (GPU), and an application specific integrated circuit (ASIC). The first semiconductor chip 100 may serve to transmit signals to the sub-semiconductor package 200 and/or to receive signals from the sub-semiconductor package 200.

As shown in FIG. 3, the first semiconductor chip 100 may include a first semiconductor substrate 110, a first wiring layer 130, first through electrodes 150, first signal pads 146a, first dummy pads 146b, and a first upper dielectric layer 142. The first semiconductor substrate 110 may include a semiconductor, such as silicon or germanium, and for example may be a silicon substrate.

The first semiconductor substrate 110 may have a first surface 110a and a second surface 110b that face or are opposite each other. The first surface 110a and the second surface 110b may respectively correspond to a bottom surface and a top surface of the first semiconductor substrate 110. A circuit layer 120 may be disposed in the vicinity of or on the first surface 110a. The circuit layer 120 may be called an active layer. The circuit layer 120 may be a section on which elements are disposed such as transistor, resistor, and condenser.

In this description, a first direction D1 is defined to indicate a direction parallel to the second surface 110b of the first semiconductor substrate 110. A second direction D2 is defined to indicate a direction that is parallel to the second surface 110b of the first semiconductor substrate 110 and intersects the first direction D1. The second direction D2 may be perpendicular to the first direction D1. A third direction D3 is defined to indicate a direction perpendicular to the second surface 110b of the first semiconductor substrate 110.

The first wiring layer 130 may be disposed on the first surface 110a of the first semiconductor substrate 110. The first wiring layer 130 may include a first dielectric layer 132, a first wiring structure 134 in the first dielectric layer 132, and first pads 136. The first pads 136 may be disposed in a lower portion of the first wiring layer 130 and may be connected to the first wiring structure 134. At least one surface of each of the first pads 136 may be exposed from the first dielectric layer 132. For example, a lower surface of the first pad 136 may be coplanar with a lower surface of the first dielectric layer 132.

The first through electrodes 150 may be conductive pillars that penetrate or extend through the first semiconductor substrate 110 and extend from the first surface 110a toward the second surface 110b. Each of the first through electrodes 150 may have one end connected to the first wiring structure 134 and another end connected to the first signal pad 146a.

As shown in FIGS. 3 and 4, the first semiconductor substrate 110 may include first regions R1 on which the first through electrodes 150 are disposed and a second region R2 other than the first regions R1. The first regions R1 may be outer sections or side portions of the first semiconductor substrate 110. For example, the first regions R1 may be spaced apart in the first direction D1 from each other across or by the second region R2.

The first semiconductor substrate 110 may be provided with the first upper dielectric layer 142, the first signal pads 146a, and the first dummy pads 146b disposed on the second surface 110b. The first signal pads 146a may be disposed on the first region R1 of the first semiconductor substrate 110, and the first dummy pads 146b may be disposed on the second region R2 of the first semiconductor substrate 110. The first signal pads 146a and the first dummy pads 146b may be exposed from the first upper dielectric layer 142. The first signal pads 146a may be correspondingly connected to the first through electrodes 150. The first upper dielectric layer 142 and the first dielectric layer 132 may each be a dielectric layer such as a silicon oxide layer, a silicon nitride layer, or a silicon oxynitride layer. The first through electrodes 150, the first wiring structure 134, the first pads 136, the first signal pads 146a, and the first dummy pads 146b may include metal such as copper, gold, or aluminum.

The connection die 300 may not include an integrated circuit, and may serve to supply the sub-semiconductor package 200 with power. Unlike the first semiconductor chip 100, the connection die 300 may neither transfer signals to the sub-semiconductor package 200 nor receive signals from the sub-semiconductor package 200. According to the present inventive concepts, the sub-semiconductor package 200 and the first semiconductor chip 100 may be connected in terms of signal transmission, and the sub-semiconductor package 200 and the connection die 300 may be connected in terms of power transmission. In contrast, the first semiconductor chip 100 and the connection die 300 may be connected in terms of neither signal nor power transmissions.

The connection die 300 may include a second semiconductor substrate 310, a second wiring layer 330, second through electrodes 350, first power pads 346, and a second upper dielectric layer 342. The second semiconductor substrate 310 may include a semiconductor, such as silicon or germanium, and for example may be a silicon substrate.

The second semiconductor substrate 310 may have a third surface 310a and a fourth surface 310b that face or are opposite each other. The second wiring layer 330 may be disposed on the third surface 310a. The second wiring layer 330 may include a second dielectric layer 332, a second wiring structure 334 in the second dielectric layer 332, and second pads 336. The second pads 336 may be disposed in a lower portion of the second wiring layer 330. The second semiconductor substrate 310 may not include a circuit layer. The second pads 336 may be disposed in a lower portion of the second wiring layer 330 and may be connected to the second wiring structure 334. At least one surface of each of the second pads 336 may be exposed from the second dielectric layer 332. For example, a lower surface of the second pad 336 may be coplanar with a lower surface of the second dielectric layer 332.

The second through electrodes 350 may vertically penetrate or extend through the second semiconductor substrate 310. Each of the second through electrodes 350 may have one end connected to the second wiring structure 334 and another end connected to the first power pad 346.

The second upper dielectric layer 342 and the second dielectric layer 332 may each be a dielectric layer such as a silicon oxide layer, a silicon nitride layer, or a silicon oxynitride layer. The second through electrodes 350, the second wiring structure 334, the second pads 336, and the first power pads 346 may include metal such as copper, gold, or aluminum.

Referring to FIGS. 3 and 6, the first through electrode 150 may have a first diameter or width W1, and the second through electrode 350 may have a second diameter or width W2. The first diameter W1 may be less than the second diameter W2. As a relatively large diameter is given to the second through electrode 350 through which power is transmitted, it may be possible to reduce loss due to resistance in power transmission procedure.

The first through electrode 150 may be electrically connected through the first wiring structure 134 on the first surface 110a of the first semiconductor substrate 110 to the first pad 136 and a transistor disposed on the circuit layer 120. The first wiring structure 134 may include first wiring layers M11, M12, M13, M14, and M15 and first vias V1 that connect the first wiring layers M11, M12, M13, M14, and M15 to each other. The first pad 136 may be in contact with a lowermost one M15 of the first wiring layers M11, M12, M13, M14, and M15. The lowermost first wiring layer M15 may have a thickness (e.g., vertical thickness) greater than that of each of other first wiring layers M11, M12, M13, and M14. According to some embodiments, the first via V1 may be additionally interposed between the first pad 136 and the first wiring layer M15. The first dielectric layer 132 is illustrated as having one layer, but actually may be formed of a plurality of dielectric layers. According to some embodiments, a first protection layer 132P may be provided on the first dielectric layer 132. The first protection layer 132P may include a dielectric material different from that of the first dielectric layer 132. The first protection layer 132P may include a dielectric material such as a silicon nitride layer or a silicon oxynitride layer. The first pad 136 may have a bottom surface at least a portion of which is exposed from the first protection layer 132P. For example, the first protection layer 132P may be on only a portion of the bottom or lower surface of the first pad 136.

A first connection terminal 180 may be provided on the exposed bottom surface of the first pad 136. The first connection terminal 180 may be interposed between the first semiconductor chip 100 and a package substrate 500 which will be discussed below. The first connection terminal 180 may include, for example, solder.

The second through electrode 350 may be electrically connected to the second pad 336 through the second wiring structure 334 on the third surface 310a of the second semiconductor substrate 310. The second wiring structure 334 may include second wiring layers M21, M22, and M23 and second vias V2 that connect the second wiring layers M21, M22, and M23 to each other. The second pad 336 may be in contact with a lowermost one M23 of the second wiring layers M21, M22, and M23. The lowermost second wiring layer M23 may have a thickness (e.g., vertical thickness) greater than that of each of other second wiring layers M21 and M22. According to some embodiments, the second via V2 may be additionally interposed between the second pad 336 and the second wiring layer M23. The second dielectric layer 332 is illustrated as having one layer, but actually may be formed of a plurality of dielectric layers. According to some embodiments, a second protection layer 332P may be provided on the second dielectric layer 332. The second protection layer 332P may include a dielectric material different from that of the second dielectric layer 332. The second protection layer 332P may include a dielectric material such as a silicon nitride layer or a silicon oxynitride layer. The second pad 336 may have a bottom surface at least a portion of which is exposed from the second protection layer 332P. For example, the second protection layer 332P may be on only a portion of the bottom or lower surface of the second pad 336. A second connection terminal 380 may be provided on the exposed bottom surface of the second pad 336. The second connection terminal 380 may be interposed between the connection die 300 and a package substrate 500 which will be discussed below.

The number of stacked first wiring layers M11 to M15 may be greater than the number of stacked second wiring layers M21 to M23. For example, the number of stacked first wiring layers M11 to M15 may be 10 to 15, and the number of stacked second wiring layers M21 to M23 may be 3 to 7. FIG. 6 is an illustration showing the number of stacked first wiring layers M11 to M15 is greater than the number of stacked second wiring layers M21 to M23, and the stack number according to the present inventive concepts may be greater or less than that shown. The first semiconductor chip 100 may be a logic chip that requires input and output of various signals, while the die 300 may merely need input and output of power, with the result that the die 300 may include wiring layers whose stack number is relatively small.

The sub-semiconductor package 200 may include a second semiconductor chip 210, third semiconductor chips 220 and 220t disposed on the second semiconductor chip 210, and a mold structure 230. In this description, the second semiconductor chip 210 may be a base chip, and thus the third semiconductor chips 220 and 220t may be called memory chips.

The base chip 210 may be a logic chip. The base chip 210 may be, for example, a memory controller.

The memory chips 220 and 220t may be stacked in the third direction D3 on the base chip 210. The memory chips 220 and 220t may be the same kind of semiconductor chip having the same circuit. The memory chips 220 and 220t may each be one of DRAM and NAND Flash.

All of the base chip 210 and the memory chips 220 and 220t may include a circuit layer. The base chip 210 and the memory chips 220 may include through electrodes. An uppermost one 220t of the memory chips 220 and 220t may not include through electrodes therein. According to some embodiments, differently from that shown, the uppermost memory chip 220t may include through electrodes. The through electrodes of the base chip 210 may be connected through micro-bumps to the through electrodes of the memory chip 220 that neighbors the base chip 210. The through electrodes of neighboring memory chips 220 may be connected to each other through micro-bumps.

Adhesion layers AD may be interposed between the base chip 210 and its neighboring memory chip 220 and between neighboring memory chips 220 and 220t. The adhesion layers AD may each be, for example, a polymer-containing non-conductive film (NCF).

The mold structure 230 may be on cover at least a portion of a top surface of the base chip 210, lateral or side surfaces of the memory chips 220 and 220t, and lateral or side surfaces of the adhesion layers AD. A top surface of the uppermost memory chip 220t may be exposed from the mold structure 230. For example, the top surface of the uppermost memory chip 220t may be coplanar with a top surface of the mold structure 230.

As shown in FIG. 5, the base chip 210 may include a signal pad region A1 and a power pad region A2. The signal pad region A1 may be a section on which are disposed second signal pads 216a in a lower portion of the base chip 210, and the power pad region A2 may be a section on which are disposed second power pads 216b in a lower portion of the base chip 210. A planar area of the signal pad region A1 may be less or smaller than that of the power pad region A2. The second signal pads 216a may be arranged at a pitch different from that at which the second power pads 216b are arranged. For example, the second signal pads 216a may be arranged at a first pitch P1, and the second power pads 216b may be arranged at a second pitch P2. The first pitch P1 may be less or smaller than the second pitch P2.

The first through electrodes 150 that correspond to the second signal pads 216a may be arranged at a third pitch, and the second through electrodes 350 that correspond to the second power pads 216b may be arranged at a fourth pitch. The third pitch may be less or smaller than the fourth pitch.

The second signal pads 216a may be correspondingly vertically spaced apart from the first signal pads 146a. The second signal pads 216a may be connected to the first signal pads 146a through signal connection terminals 284. According to some embodiments, the signal connection terminals 284 may be omitted, and the second signal pads 216a may be in contact with the first signal pads 146a.

The second power pads 216b may be correspondingly vertically spaced apart from the first power pads 346. The second power pads 216b may be connected to the first power pads 346 through power connection terminals 282. According to some embodiments, the power connection terminals 282 may be omitted, and the second power pads 216b may be in contact with the first power pads 346.

The signal connection terminals 284 and the power connection terminals 282 may include a conductive material such as solder.

The dummy die 400 may be provided on the second region R2 of the first semiconductor substrate 110. The dummy die 400 may be disposed on a central section or portion of the first semiconductor substrate 110. The dummy die 400 may include a third semiconductor substrate 410, a third dielectric layer 422, and second dummy pads 426. Unlike the first semiconductor chip 100 and the connection die 300, the dummy die 400 may not include a wiring layer. The second dummy pads 426 may vertically overlap the first dummy pads 146b. The second dummy pads 426 may be connected to the first dummy pads 146b through heat transfer terminals 480. The heat transfer terminals 480 may include a conductive material such as solder.

The semiconductor package 1000 according to the present inventive concepts may further include a package substrate 500.

The package substrate 500 may be disposed on a bottom surface of the first semiconductor chip 100 and bottom surfaces of the connection dies 300. The package substrate 500 may be, for example, a printed circuit board (PCB).

The package substrate 500 may include first upper metal pads 510a, second upper metal pads 510b, lower metal pads 520, metal lines, and external connection terminals 580. The first upper metal pads 510a and the second upper metal pads 510b may be disposed in or on an upper portion of the package substrate 500, and the lower metal pads 520 may be disposed in or on a lower portion of the package substrate 500. The metal lines may connect the lower metal pads 520 to the first upper metal pads 510a and the second upper metal pads 510b.

The first connection terminals 180 may be disposed between the first upper metal pads 510a and the first pads 136. The second connection terminals 380 may be disposed between the second upper metal pads 510b and the second pads 336. The external connection terminals 580 may be correspondingly disposed on the lower metal pads 520. The first connection terminals 180, the second connection terminals 380, and the external connection terminals 580 may include a conductive material such as solder.

Referring back to FIG. 2, the first semiconductor chip 100 may have a first width X1 in the first direction D1 (e.g., horizontal width). The sub-semiconductor package 200 may have a second width X2 in the first direction D1 (e.g., horizontal width). The connection die 300 may have a third width X3 in the first direction D1 (e.g., horizontal width). The first width X1 may be greater than the second width X2 and the third width X3. The second width X2 may be greater than the third width X3. For example, the first width X1 may range from about 20 mm to about 30 mm, and the second width X2 may range from about 10 mm to about 15 mm.

The first width X1 may be a spacing distance between facing or opposite lateral or side surfaces in the first direction D1 of the first semiconductor chip 100. The second width X2 may be a spacing distance between facing or opposite lateral or side surfaces in the first direction D1 of the base chip 210. The third width X3 may be facing or opposite lateral or side surfaces in the first direction D1 of the connection die 300.

The sub-semiconductor packages 200 may be spaced apart in the first direction D1 from each other across the dummy die 400 (e.g., with the dummy die 400 therebetween). The connection dies 300 may be spaced apart in the first direction D1 from each other across the first semiconductor chip 100 (e.g., with the first semiconductor chip 100 therebetween). A first interval or spacing U1 between the sub-semiconductor packages 200 that are spaced apart from each other in the first direction D1 may be less than a second interval or spacing U2 between the connection dies 300 that are spaced apart from each other in the first direction D1. The first interval U1 may be less than the first width X1. When viewed in plan, the first through electrodes 150 may be spaced apart from the dummy die 400 (see FIG. 3). For example, the first through electrodes 150 may be horizontally spaced apart or horizontally offset from the dummy die 400.

In the semiconductor package 1000 according to the present inventive concepts, the first semiconductor chip 100 or a logic chip and the high bandwidth memory 200 may be connected to each other without a silicon interposer. For a high performance chip such as CPU, GPU, and ASIC, an increase in the number of I/O terminals may induce an increase in size of the high performance chip. When a silicon interposer is used to horizontally locate the first semiconductor chip 100 and the high bandwidth memory 200, the silicon interposer may require a wiring line through which the first semiconductor chip 100 and the high bandwidth memory 200 are connected in a horizontal direction and a through electrode that is connected to a package substrate. In this case, the wiring line is required to have a length of as much as 6 mm, and a wiring resistance may cause power loss and/or signal loss.

According to the present inventive concepts, the first semiconductor chip 100 may include the first through electrodes 150, and may be connected through the first through electrodes 150 to the high bandwidth memory 200. As a result, in comparison with a case where an interposer is used, the present inventive concepts may have a reduced electrical path and a decreased latency in signal processing procedure. In addition, as the connection die 300 is used which includes the second through electrodes 350 through which a power is supplied, the first semiconductor chip 100 may not need additional through electrodes for power transmission. Accordingly, it may be possible to reduce process difficulty and to more efficiently design the first semiconductor chip 100.

In a case where a silicon interposer is used, it may be required that a package substrate have a size greater than that of the silicon interposer. Compared to a case where the first semiconductor chip 100 and the high bandwidth memory 200 are horizontally disposed on a silicon interposer, the present inventive concepts may reduce a horizontal width by allowing the first semiconductor chip 100 and the high bandwidth memory 200 to rest in a vertical direction. Therefore, it may be possible to achieve a semiconductor package having a smaller required width of a package substrate, a reduced cost, and a decreased area.

In a method of fabricating the semiconductor package 1000 according to the present inventive concepts, the package substrate 500 may be prepared. The first semiconductor chip 100 and the connection dies 300 may be mounted on the package substrate 500. The sub-semiconductor packages 200 and the dummy die 400 may be mounted on the first semiconductor chip 100 and the connection dies 300, and thus the semiconductor package 1000 may be eventually fabricated.

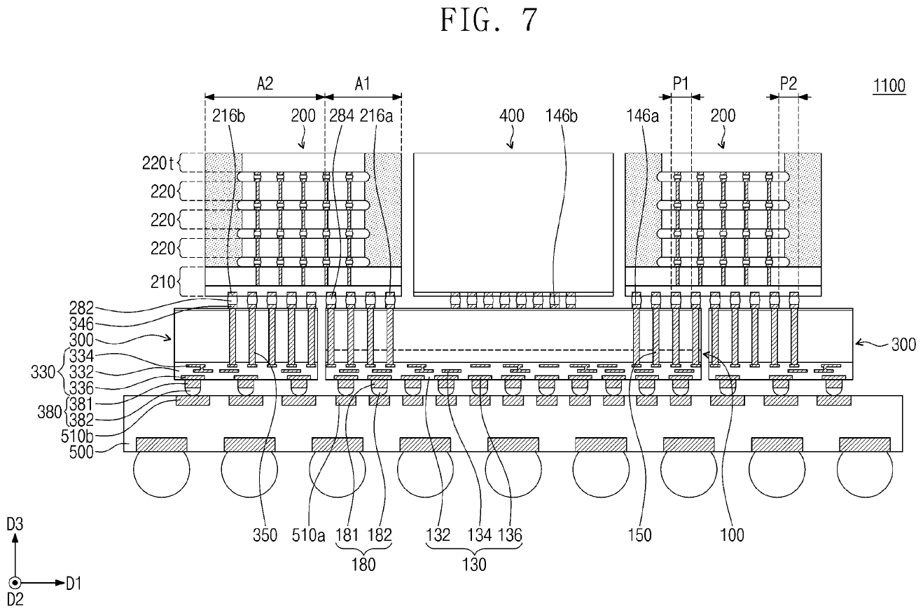

FIG. 7 illustrates a simplified cross-sectional view showing a semiconductor package according to some embodiments of the present inventive concepts. In the interest of brevity, omission will be made to avoid duplicate descriptions of components included in the semiconductor package discussed with reference to FIG. 3, except the following explanations.

Referring to FIG. 7, a semiconductor package 1100 according to some embodiments may include the base chip 210 in which the second signal pads 216a and the second power pads 216b are arranged at the same pitch. For example, the first pitch P1 and the second pitch P2 may be substantially the same as each other.

The first connection terminals 180 may each include a first pillar bump 181 and a first bump solder cap 182. The first pillar bump 181 may be in contact with the first pad 136. The first bump solder cap 182 may be in contact with the first upper metal pad 510a. The second connection terminals 380 may each include a second pillar bump 381 and a second bump solder cap 382. The second pillar bump 381 may be in contact with the second pad 336. The second bump solder cap 382 may be in contact with the second upper metal pad 510b.

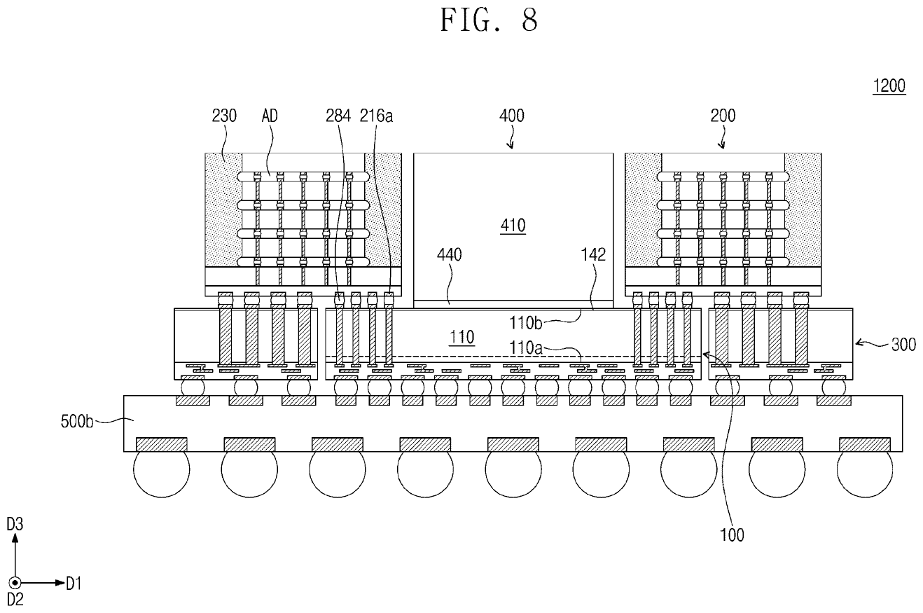

FIG. 8 illustrates a simplified cross-sectional view showing a semiconductor package according to some embodiments of the present inventive concepts. In the interest of brevity, omission will be made to avoid duplicate description of the semiconductor package discussed with reference to FIG. 3, except the following explanations.

Referring to FIG. 8, a semiconductor package 1200 according to some embodiments may include a heat transfer layer 440 instead of the first dummy pads 146b, the heat transfer terminals 480, and the third dielectric layer 422 of FIG. 3. The heat transfer layer 440 may include a thermal interface material (TIM). The heat transfer layer 440 may be in contact with the first upper dielectric layer 142.

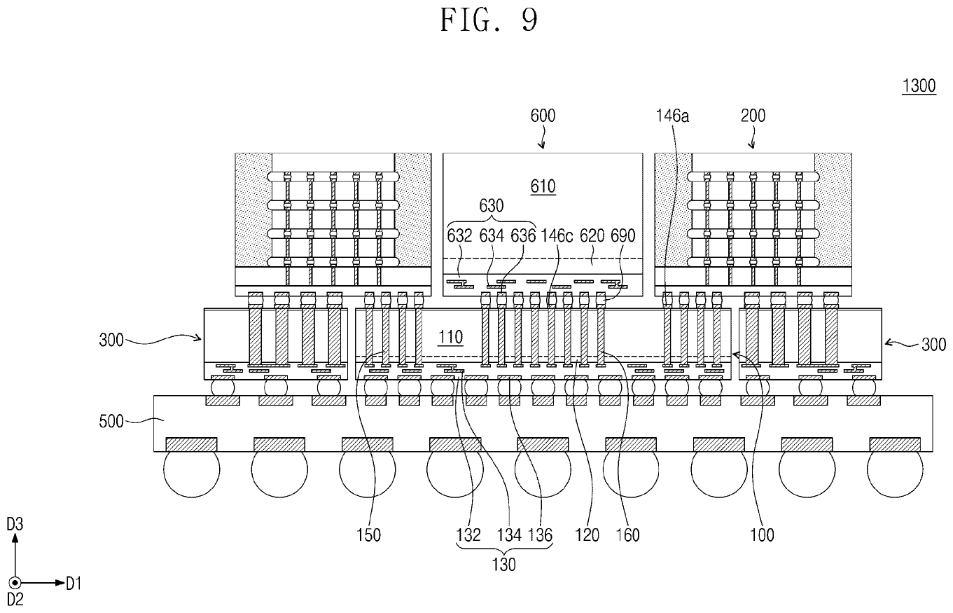

FIG. 9 illustrates a simplified cross-sectional view showing a semiconductor package according to some embodiments of the present inventive concepts. In the interest of brevity, omission will be made to avoid duplicate description of the semiconductor package discussed with reference to FIG. 3, except the following explanations.

Referring to FIG. 9, a semiconductor package 1300 according to some embodiments may include a fourth semiconductor chip 600 instead of the dummy die 400.

The fourth semiconductor chip 600 may include a third semiconductor substrate 610, a second circuit layer 620, and a third wiring layer 630. The fourth semiconductor chip 600 may be a memory chip such as DRAM or SRAM.

The third wiring layer 630 may include a third dielectric layer 632, a third wiring structure 634, and third pads 636 that respectively correspond to the first dielectric layer 132, the first wiring structure 134, and the first pads 136 of the first wiring layer 130 discussed above.

The first semiconductor chip 100 may further include third through electrodes 160 that vertically overlap the third pads 636. There may be provided bonding pads 146c instead of the first dummy pads 146b depicted in FIG. 3. Each of the third through electrodes 160 may have one end connected to the first wiring structure 134 and another end connected to the bonding pads 146c. Third connection terminals 690 may be interposed between the third pads 636 and the bonding pads 146c. The fourth semiconductor chip 600 may receive and transmit signals with the first semiconductor chip 100 through the third through electrodes 160 or may be supplied with power through the third through electrodes 160.

A semiconductor package according to the present inventive concepts may not include a wiring line for horizontal connection or a silicon interposer including a through electrode. In the present inventive concepts, a high bandwidth memory and a logic chip may be connected to each other without the silicon interposer. The high bandwidth memory may be disposed on a logic chip including first through electrodes and a connection die including second through electrodes. The high bandwidth memory may be disposed in a vertical direction on the first through electrodes and the second through electrodes. In the present inventive concepts, because the high bandwidth memory and the logic chip are disposed in a vertical direction and connected to each other through the first through electrodes, it may be possible to omit a wiring line for horizontally connecting the logic chip and the high bandwidth memory. As a result, an electrical path may be reduced, and reliability of semiconductor packages may be increased.

This detailed description of the present inventive concepts should not be construed as limited to the embodiments set forth herein, and it is intended that the present inventive concepts cover the various combinations, modifications and variations of this disclosure without departing from the spirit and scope of the present inventive concepts.

What is claimed is:

1. A semiconductor package, comprising:
a first semiconductor chip;
a connection die adjacent a side surface of the first semiconductor chip; and
a second semiconductor chip on the first semiconductor chip and the connection die,
wherein the first semiconductor chip includes a plurality of first through electrodes,
wherein the connection die includes a plurality of second through electrodes, and
wherein the first through electrodes and the second through electrodes are below and vertically overlap the second semiconductor chip.

2. The semiconductor package of claim 1, wherein
the first semiconductor chip includes a circuit layer, and
the connection die does not include a circuit layer.

3. The semiconductor package of claim 1, wherein
the plurality of first through electrodes each have a first diameter,
the plurality of second through electrodes each have a second diameter, and
the first diameter is smaller than the second diameter.

4. The semiconductor package of claim 1, wherein
the plurality of first through electrodes are arranged at a first pitch,
the plurality of second through electrodes are arranged at a second pitch, and
the first pitch is smaller than the second pitch.

5. The semiconductor package of claim 1, wherein
the first semiconductor chip is a logic chip, and
the second semiconductor chip is a memory chip.

6. The semiconductor package of claim 1, further comprising a dummy die on the first semiconductor chip,
wherein the second semiconductor chip is on an outer section of the first semiconductor chip, and
wherein the dummy die is on a central section of the first semiconductor chip.

7. The semiconductor package of claim 6, wherein
the connection die comprises a plurality of connection dies and the second semiconductor chip comprises a plurality of second semiconductor chips,
the second semiconductor chips are spaced apart in a first direction from each other with the dummy die therebetween,
the connection dies are spaced apart in the first direction from each other with the first semiconductor chip therebetween, and
a spacing distance between the second semiconductor chips is smaller than a spacing distance between the connection dies.

8. The semiconductor package of claim 6, wherein
the first semiconductor chip further includes a plurality of first dummy pads in or on an upper portion thereof,
the dummy die includes a plurality of second dummy pads in or on a lower portion thereof, and
the semiconductor package further comprises a plurality of heat transfer terminals between the first dummy pads and the second dummy pads.

9. The semiconductor package of claim 6, further comprising a heat transfer layer between the first semiconductor chip and the dummy die,
wherein the heat transfer layer includes a thermal interface material (TIM).

10. The semiconductor package of claim 1, further comprising a third semiconductor chip on the first semiconductor chip, wherein
the second semiconductor chip is on an outer section of the first semiconductor chip,
the third semiconductor chip is on a central section of the first semiconductor chip,
the first semiconductor chip further includes a plurality of third through electrodes, and
the third through electrodes are below and vertically overlap the third semiconductor chip.

11. The semiconductor package of claim 1, wherein
the first semiconductor chip further includes a plurality of first wiring layers that are connected to the first through electrodes and are vertically stacked,
the connection die further includes a plurality of second wiring layers that are connected to the second through electrodes and are vertically stacked, and
a number of the stacked first wiring layers is greater than a number of the stacked second wiring layers.

12. A semiconductor package, comprising:
a first semiconductor chip;
a connection die horizontally spaced apart from a side surface of the first semiconductor chip; and
a second semiconductor chip on the first semiconductor chip and the connection die,
wherein each of the first semiconductor chip and the connection die includes a plurality of through electrodes,
wherein the second semiconductor chip vertically overlaps an outer section of the first semiconductor chip and at least a portion of the connection die, and
a central section of the first semiconductor chip is horizontally offset from the second semiconductor chip.

13. The semiconductor package of claim 12, wherein
the first semiconductor chip has a first width in a first direction,
the second semiconductor chip has a second width in the first direction,
the connection die has a third width in the first direction,
the first width is greater than the second width, and
the second width is greater than the third width.

14. The semiconductor package of claim 13, wherein
the first width is in a range of about 20 mm to about 30 mm, and
the second width is in a range of about 10 mm to about 15 mm.

15. The semiconductor package of claim 12, wherein the second semiconductor chip includes:
a first region that vertically overlaps the first semiconductor chip; and
a second region that vertically overlaps the connection die,
wherein a planar area of the first region is smaller than a planar area of the second region.

16. The semiconductor package of claim 12, wherein
the second semiconductor chip includes a plurality of signal pads and a plurality of power pads in or on a lower portion thereof,
the signal pads are arranged at a first pitch on the first semiconductor chip,
the power pads are arranged at a second pitch on the connection die, and
the first pitch is smaller than the second pitch.

17. A semiconductor package, comprising:
a package substrate;
a logic chip on the package substrate;
a first connection die and a second connection die that are spaced apart in a first direction from each other with the logic chip therebetween;
a first sub-semiconductor package on the logic chip and the first connection die; and
a second sub-semiconductor package on the logic chip and the second connection die,
wherein a spacing distance in the first direction between the first sub-semiconductor package and the second sub-semiconductor package is less than a width in the first direction of the logic chip,
wherein each of the first sub-semiconductor package and the second sub-semiconductor package includes:
a base chip;
a plurality of memory chips on the base chip; and
a mold structure on the base chip and the memory chips, and
wherein each of the logic chip, the first connection die, the second connection die, the base chip, and the memory chips includes a plurality of through electrodes.

18. The semiconductor package of claim 17, further comprising a dummy die on the logic chip and between the first connection die and the second connection die,
wherein the through electrodes of the logic chip are horizontally spaced apart from the dummy die.

19. The semiconductor package of claim 17, wherein
the logic chip is configured to transmit or receive a signal to or from the first sub-semiconductor package and the second sub-semiconductor package, and
the first connection die and the second connection die are configured to provide power to the first sub-semiconductor package and the second sub-semiconductor package, respectively.

20. The semiconductor package of claim 17, wherein neither the first connection die nor the second connection die includes a circuit layer.
